(19) United States
(12) Patent Application Publication
(10) Pub. No.: US 2011/0212600 A1
(43) Pub. Date: Sep. 1, 2011

(54) METHOD FOR FORMING CHANNEL LAYER WITH HIGH GE CONTENT ON SUBSTRATE

(75) Inventor: Jing WANG, Beijing, P.R. (CN)

(73) Assignee: Tsinghua University, Beijing, PR (CN)

(21) Appl. No.: 13/063,649

(22) PCT Filed: Jul. 21, 2010
(86) PCT No.: PCT/CN10/75375

§ 371 Date: Mar. 11, 2011

(30) Foreign Application Priority Data
Dec. 11, 2009 (JP) 200910242318.X

(51) Int. Cl. H01L 21/20

(52) U.S. Cl. 438/478; 257/E21.09

(57) ABSTRACT

A method for forming a channel layer with high Ge content on a substrate is provided. The method may comprise steps of: preparing the substrate (110), forming a dielectric layer (120) on the substrate (110), lithographing and etching the dielectric layer (120) to form at least one hole in the dielectric layer to grow a channel layer (130) with high Ge content; and growing the channel layer with high Ge content (130) in the at least one hole by a low temperature reduced pressure chemical vapor deposition (RPCVD).

### FIELD

The present disclosure relates to semiconductor manufacture and design, and more particularly to a method for forming a channel layer with high Ge content on a substrate by combining low-temperature reduced pressure chemical vapor deposition (RPCVD) with selective epitaxial process.

### BACKGROUND

In semiconductor fields, Si is the dominant semiconductor material for many years and has been proved to have an excellent performance. However, the critical size scaling down gradually reaches to physical limit of the semiconductor device. Therefore, a CMOS device with silicon as channel material has a lowered mobility, which may not meet performance improvement thereof. In order to solve this problem, conventionally, strained silicon techniques are adopted to improve the mobility of silicon, or other materials with higher mobility are used to replace the silicon as the channel material for the device, among which Ge has been paid more attention than ever before because of its higher hole mobility. Because researches have shown that Ge or SiGe with high Ge content both have a much higher hole mobility than Si, Ge or SiGe is most suitable for fabricating PMOS devices in future CMOS process. However, because current Si processes and equipments are quite mature, considering cost and compatibility requirements thereof, a Si wafer may be used as a substrate, and various processes may be used to form a Ge layer or a SiGe layer with high Ge content on a surface of the Si wafer to be used as a channel layer of the device. Thus, a high carrier mobility thereof may be achieved and the device performance may be improved accordingly.

However, since Ge has a lattice constant different from that of Si, there is 4.2% lattice mismatch between Si and Ge. Therefore, if the Ge layer or the SiGe layer with high Ge content is directly grown on the Si substrate, many dislocations may be generated which may punch through to the surface to negatively cause device defects, which may greatly deteriorate the performance of the fabricated MOS devices. Therefore, this process may not be used in preparing the semiconductor MOS devices. Currently, some new processes and technologies have been proposed to fabricate a device having a channel layer with high Ge content, which may possess low density of dislocations punching through to the surface so that they may be used in the fabrication of these devices.

Amongst therein, a conventional method relates to a direct epitaxy of high Ge content material on a blank Si wafer. Several processes and methods are used to reduce the density of dislocations punching through to the surface so as to reduce a surface defect density of the fabricated devices. For example, the high Ge content material may be obtained by an epitaxy of the SiGe layer with variable Ge content, by performing thermal oxidation concentration on the SiGe layer with low Ge content, rapid thermal annealing or secondary forming etc. These methods as mentioned may have advantages of overall epitaxy on the wafer, which is convenient for the fabrication of the MOS devices in subsequent processes in addition to compatibility with conventional processes. However, these methods may have disadvantages such as a rough surface, a thick epitaxy layer, and complicated processes with a high surface defect density. Meanwhile, due to a limitation of the overall heterogeneous epitaxy process itself, the material formed also has a high density of dislocations punching through to the surface, which is not suitable for fabricating nanometer scaled CMOS device in future.

Another conventional method uses a selective epitaxy process, in which a dielectric layer is deposited on a Si wafer, a hole with a high aspect ratio is formed therein by lithographing and etching, the single crystal silicon material is exposed at a bottom surface of the etched hole, and then crystal material with high Ge content is grown by an Ultra-high Vacuum Chemical Vapor Deposition (UHVCVD). According to the selective epitaxy process, the hole has a vertical side wall blocking a continuous extension of a dislocation, and the dislocation may be blocked and not extend to the surface accordingly. Therefore, a side wall with a certain height may filter most of the dislocations to obtain the channel layer with high Ge content having a low surface defect density. Thus, the MOS devices may be fabricated in high quality areas with high Ge content. In the remaining areas covered by insulating dielectrics, it is difficult for the crystal material with high Ge content to nucleate, gases such as HCl may be introduced into the RPCVD process at the same time to block the nucleation thereof through etching of the crystal material on the dielectrics. Thus, it may be ensured that growth of the crystal material with high Ge content mainly occurs in areas of the Si substrate exposed in the hole, so that the desired channel layer may be obtained in the desired area.

However, according to this method, a lot of dislocations extend perpendicularly upward, and both side walls may not block these dislocations. Therefore, the channel layer with high Ge content fabricated according to this method may not meet practical requirements due to the rough surface and high surface defect density thereof.

### SUMMARY

In viewing thereof, according to the present disclosure, a selective epitaxial process and a low-temperature reduced pressure chemical vapor deposition (RPCVD) process may be combined to form a channel layer with high Ge content on a substrate such as silicon substrate, which may possess a lowered surface roughness, reduced epitaxy layer thickness and a lowered surface defect density, in which the channel layer may be a SiGe layer or a Ge layer with high Ge content. The channel layer with high Ge content according to the present disclosure may be used in the fabrication of semiconductor devices.

According to an embodiment of the present disclosure, a method for forming a channel layer with high Ge content on a substrate may be provided. And the method may comprise steps of: preparing the substrate; forming a dielectric layer on the substrate; lithographing and etching the dielectric layer to form at least one hole in the dielectric layer to grow a channel layer with high Ge content; and growing the channel layer with high Ge content in the at least one hole by a low temperature reduced pressure chemical vapor deposition.

In step (1), a blank Si wafer may be selected as a substrate, or a Si wafer with an epitaxy of a SiGe layer with low Ge content may be selected as a substrate, and then the substrate may be cleaned accordingly. For the SiGe layer with low Ge content, the Ge content in the SiGe layer may be not larger than about 30%.

In step (2), a SiO₂ dielectric layer with a predetermined or desired thickness is formed on the substrate by a low-pressure chemical vapor deposition (LPCVD) or a plasma enhanced chemical vapor deposition (PECVD) according to a size and an aspect ratio of the hole in the channel layer with high Ge content. For the channel layer with high Ge content, the Ge content is about 50%-100%. The thickness of the SiO₂ dielectric layer is between dozens of nanometer and several micrometers (um).

In step (3), the hole with a predetermined size is etched out on the SiO₂ dielectric layer along different crystal orientations by lithographing and dry etching. The aspect ratio of the hole is larger than 1. A single crystal substrate exposed at the bottom of the hole may be cleaned.

In step (4), a selective epitaxy of the channel material layer with high Ge content may be performed on the single crystal substrate exposed at the bottom of the hole by a low-temperature RPCVD at an epitaxy temperature of about 350° C.-550° C., preferably about 450° C.-550° C. According to an embodiment of the present disclosure, this channel layer with high Ge content may be a single layer, for example a Ge layer or a SiGe layer with high Ge content. According to another embodiment of the present disclosure, this channel layer with high Ge content may comprise two layers, for example a first relaxed SiGe layer with high Ge content formed epitaxially and a second strained SiGe layer with higher Ge content or a second strained Ge layer formed epitaxially.

According to an embodiment of the present disclosure, a high quality channel layer with high Ge content with the dislocation density lower than 10⁶ cm⁻², the surface roughness less than 1 nm and the layer thickness being reduced may be provided. This channel layer may be a Ge layer or a SiGe layer with a high Ge content, and may be used in the fabrication of future MOS devices.

Additional aspects and advantages of the embodiments of present invention will be given in part in the following descriptions, become apparent in part from the following descriptions, or be learned from the practice of the embodiments present invention.

### BRIEF DESCRIPTION OF THE DRAWINGS

These and other aspects and advantages of the invention will become apparent and more readily appreciated from the following descriptions taken in conjunction with the drawings in which:

FIG. 1 is a Transmission Electron Microscopy (TEM) image taken at an interface between Si and SiGe of a SiGe layer with high Ge content which is formed epitaxially at 500° C. by a low temperature RPCVD process according to an embodiment of the present disclosure;

FIG. 2 is an Atomic Force Microscope (AFM) image taken at a surface of a SiGe layer with high Ge content which is grown at 500° C. by a low temperature RPCVD process according to an embodiment of the present disclosure;

FIG. 3 is a flow chart for forming a SiGe layer with high Ge content on a substrate by combining a low-temperature RPCVD process and a selective epitaxial process according to an embodiment of the present disclosure;

FIG. 4 is a cross-sectional view showing a a SiGe layer with high Ge content formed on a silicon substrate according to a first embodiment of the present disclosure;

FIG. 5 is a cross-sectional view showing a SiGe layer with high Ge content formed on a silicon substrate according to a second embodiment of the present disclosure;

FIG. 6 is a cross-sectional view showing a SiGe layer with high Ge content formed on a silicon substrate according to a third embodiment of the present disclosure;

FIG. 7 is a cross-sectional view showing a SiGe layer with high Ge content formed on a silicon substrate according to a fourth embodiment of the present disclosure; and

FIG. 8 is a cross-sectional view showing a SiGe layer with a high Ge content formed on a silicon substrate according to a fifth embodiment of the present disclosure.

### DETAILED DESCRIPTION OF EMBODIMENTS OF THE INVENTION

Embodiments of the present disclosure will be described in detail in the following descriptions, examples of which are shown in the accompanying drawings, in which the same or similar elements and elements having same or similar functions are denoted by like reference numerals throughout the descriptions. The embodiments described herein with reference to the accompanying drawings are explanatory and illustrative, which are used to generally understand the present disclosure. The embodiments shall not be construed to limit the present disclosure.

Various embodiments and examples are provided in the following description to implement different structures of the present disclosure. In order to simplify the present disclosure, certain elements and settings will be described. However, these elements and settings are only examples and are not intend to limit the present disclosure. In addition, reference numerals may be repeated in different examples in the disclosure. This repeating is for the purpose of simplification and clarity and does not refer to relations between different embodiments and/or settings. Furthermore, examples of different processes and materials are provided in the present disclosure. However, it is appreciated for those skilled in the art to understand that other processes and/or materials may be also applied. Moreover, a structure in which a first feature is “on” a second feature may include an embodiment in which the first feature directly contacts the second feature and may include an embodiment in which an additional feature is prepared between the first feature and the second feature so that the first feature does not directly contact the second feature.

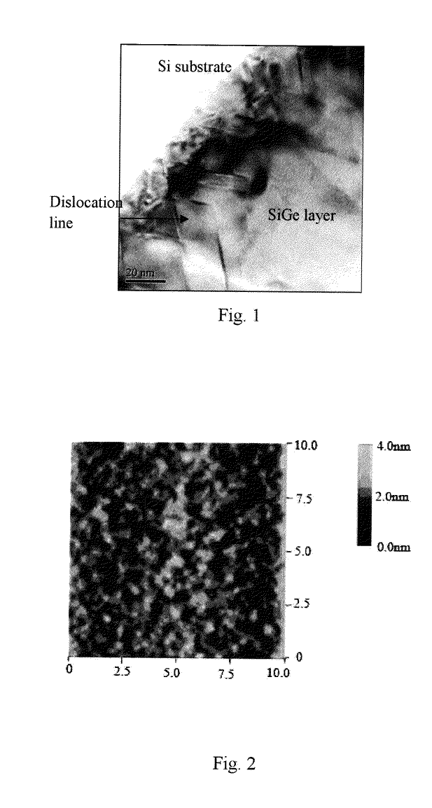

After years of research on forming a SiGe single crystal thin film with high Ge content on a substrate by low-temperature RPCVD, it has been found by the inventors that when an epitaxy temperature is within 350° C.-550° C., preferably within 450° C.-550° C., and GeH₄ and SiH₄ may be used as precursors for epitaxy to grow the SiGe thin film, most dislocations caused by lattice mismatch are generated within a thin layer at a Si/SiGe interface, and these dislocations are extended upward into the SiGe layer with an angle of 60 degrees with respect to the interface of the Si/SiGe. The dislocations extending perpendicularly in the upward direction are very rare. As shown in FIG. 1, which is a TEM image taken at a Si/SiGe interface according to an embodiment of the present disclosure, the dislocations are extended upwardly into the SiGe layer with an angle of 60 degrees with respect to the Si/SiGe interface and there are very few dislocations in the perpendicular direction.

With respect to the above features found according to the embodiment of the present disclosure, by blocking the extended dislocations generated due to lattice mismatches from extending to the surface of the SiGe layer by side walls, most dislocations are filtered by combining the low-temperature RPCVD process with the selective epitaxial process. Therefore, most dislocations extending upwardly may be blocked by the side wall with the reduced thickness, thus the thickness of the epitaxy layer is also reduced accordingly. Furthermore, since the dislocations extending perpendicularly upward are very rare, the dislocation density thereof may be further reduced compared with other epitaxial processes.

As an additional advantage of the present disclosure, the low-temperature RPCVD epitaxy may effectively reduce a surface roughness of the grown SiGe layer. As shown in FIG. 2, which is an AFM image taken at a surface of a SiGe layer with high Ge content grown at 500° C. by a low temperature RPCVD process according to an embodiment of the present disclosure, the epitaxial layer has a thickness of about 400 nm and a surface roughness RMS of about 0.389 nm. Therefore, the material formed according to an embodiment of the present disclosure has advantages in fabricating subsequent devices and preventing random extensions of dislocations, and therefore may be applied directly to the fabrication of devices, thus avoiding an additional chemical mechanical polishing (CMP) process.

According to an embodiment of the present disclosure, by combining the low-temperature RPCVD process with the selective epitaxial process, a high quality channel layer with high Ge content whereas with a low dislocation density, a reduced layer thickness and a lowered surface roughness may be formed. This channel layer may be a Ge layer or a SiGe layer with high Ge content, and may be used during the fabrication of future MOS devices with high performance.

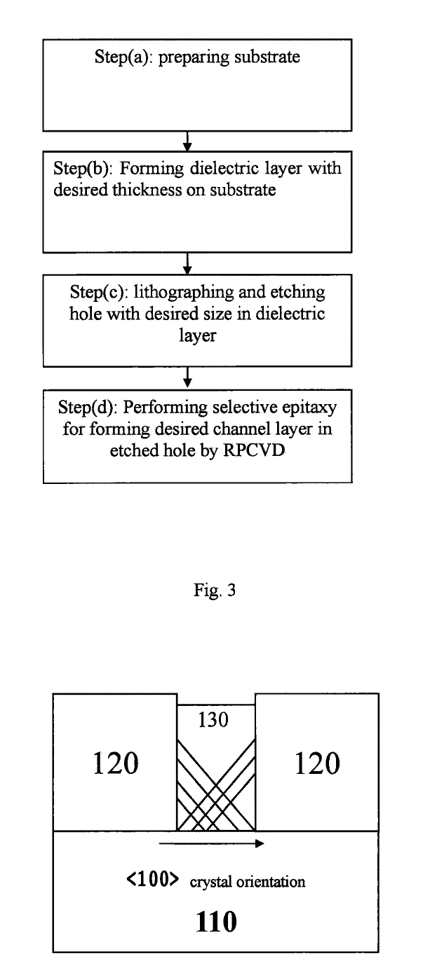

FIG. 3 mainly shows a flow chart for forming a SiGe layer with high Ge content on a substrate. As shown in FIG. 3, the channel layer with high Ge content is formed by combining the low-temperature RPCVD process with the selective epitaxial process, and this channel layer may be a Ge layer or a SiGe layer with high Ge content. The method may include following steps.

In step (a), a substrate is provided and cleaned. According to the present method, a blank Si wafer may be used as the substrate, or the Si wafer with a grown SiGe layer with low Ge content may be used as the substrate. The grown SiGe layer with low Ge content may be a SiGe layer having a Ge content less than 30%.

In step (b), a dielectric layer with a desired thickness is formed on the substrate. In an embodiment of the present disclosure, the thickness of a SiO₂ dielectric layer may be determined according to an epitaxial hole size desired for the selective epitaxy of SiGe or Ge. Generally an aspect ratio of the etched hole is required to be larger than 1. Depending on different practical requirements, the thickness of the SiO₂ dielectric layer varies from dozens of nanometers to several urn, and different preparing methods may be selected, for example, thermal oxidization, LPCVD or PECVD and sputtering etc.

In step (c), the hole with the desired size is formed in the dielectric layer. The hole with a desired aspect ratio is formed on the SiO₂ dielectric layer along different crystal orientations by lithographing and dry etching. The substrate at the bottom of the hole is exposed and cleaned accordingly.

In step (d), the desired material layer is grown in the hole thus formed. According to an embodiment of the present disclosure, the selective epitaxy may be carried out in the hole by a low-temperature RPCVD at an epitaxy temperature of about 350° C.-550° C., preferably at about 450° C.-550° C., so that the high quality channel layer with a high Ge content may be selectively grown on the substrate exposed in the etched hole. According to an embodiment of the present disclosure, this channel layer with high Ge content may be a single layer, for example a Ge layer or a SiGe layer with a high Ge content. According to another embodiment of the present disclosure, this channel layer with high Ge content may comprise two layers, for example a first relaxed SiGe layer with high Ge content prepared epitaxially and a second strained SiGe layer with a higher content Ge or a second strained Ge layer prepared epitaxially. Specifically, the relaxed SiGe layer with more than 50% Ge content is firstly grown on the substrate, and then the strained SiGe layer with a higher content Ge or the strained Ge layer is grown on the relaxed SiGe layer.

According to an embodiment of the present disclosure, after the above steps, a high quality channel layer with high Ge content on a substrate may be formed accordingly, the channel layer has a high Ge content with the dislocation density lower than 10⁶ cm⁻², the surface roughness smaller than 1 nm with reduced thickness. This channel layer may be a Ge layer or a SiGe layer with a high Ge content, and may be used in the fabrication of future high performance MOS devices.

In order to understand the present disclosure more clearly, detailed examples will be described. It should be noted that the following are only preferred embodiments of the present disclosure. It would be appreciated by those skilled in the art that changes and to alternatives may be made without departing from the technical principles of the disclosure, and these changes and alternatives should be within the scope of the disclosure.

### EXAMPLE 1

Firstly, a Si substrate 110 is prepared. A SiO₂ dielectric layer 120 with a desired thickness (for example 1 um) is deposited or grown on the Si substrate 110 by the low-pressure CVD (LPCVD) process according to the size of the desired channel layer with high Ge content. The hole with a desired size (for example with a length of 500 nm) is formed in the SiO₂ dielectric layer 120 along <100> crystal orientation of the Si substrate 110 by lithographing and etching. The obtained hole has an aspect ratio of 2 to guarantee that the side wall, i.e. the SiO₂ dielectric layer 120, of the hole may filter most dislocation lines. Then Ge or SiGe with high Ge content is grown at 500° C. by a RPCVD equipment to form a channel layer 130 with high Ge content.

According to this example, taking SiGe with high Ge content as an example, GeH₄ with a flow rate of about 400 sccm and SiH₄ with a flow rate of about 0.05 slm may be used as precursors, and at the same time a HCl gas with a flow rate of about 0.10 slm is introduced to reduce the nucleating rate and the growth rate of SiGe on the SiO₂ dielectric layer 120. Therefore, the SiGe epitaxy occurs on the Si substrate 110 exposed in the hole to guarantee a two dimensional SiGe growth so that the SiGe layer with high Ge content may possess a desired low dislocation density with a low surface roughness.

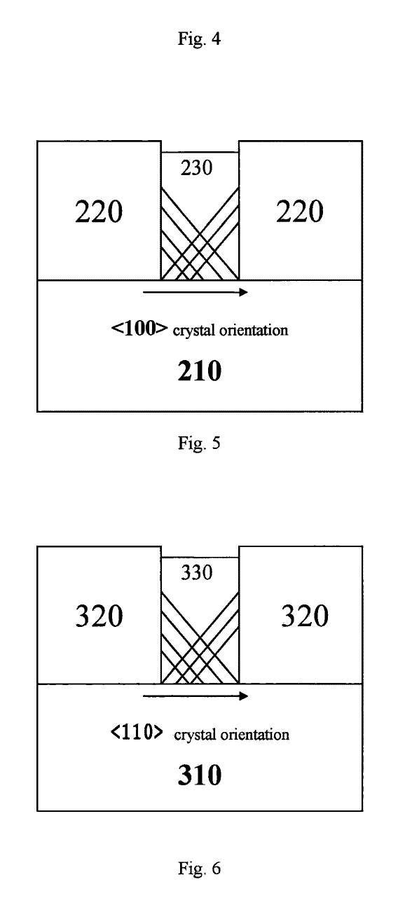

In this example, the obtained SiGe layer has a Ge content of about 87%, a dislocation density lower than 10⁶ cm⁻² and a surface roughness smaller than 1 nm, and consequently is desirable for the fabrication of MOS devices in the CMOS process. A semiconductor structure having the SiGe layer with high Ge content is shown in FIG. 4. In this example, although the growth of the SiGe layer with high Ge content is taken as an example, the Ge layer may be formed or grown by selecting an appropriate precursor.

### EXAMPLE 2

Firstly, a Si substrate 210 is provided and cleaned. A SiO₂ dielectric layer 220 with a desired thickness (for example 1 um) is formed on the Si substrate 210 by the LPCVD process according to the size of the desired channel layer with high Ge content. The hole with a desired size (for example with a length of 500 nm) is formed on the SiO₂ dielectric layer 220 along <100> crystal orientation of the Si substrate 210 by lithographing and etching. The obtained hole has an aspect ratio of 2 to guarantee that the side wall, i.e. the SiO₂ dielectric layer 220, of the hole may filter most dislocations. Then the Ge or SiGe with high Ge content is grown at 550° C. by a RPCVD device to form a channel layer 230 with high Ge content. According to this example, taking SiGe with high Ge content as an example, GeH₄ with a flow rate of about 200 sccm and SiH₄ with a flow rate of about 0.05 slm may be used as precursors and at the same time a HCl gas with a flow rate of about 0.10 slm is introduced to reduce the nucleating rate and the growth rate of SiGe on the SiO₂ dielectric layer 220. Therefore, the SiGe epitaxy occurs on the Si substrate 110 exposed in the hole to guarantee a two dimensional SiGe growth so that the SiGe layer with high Ge content formed on the silicon substrate may be provided, the SiGe layer may have a desired low dislocation density with a low surface roughness. In this example, the obtained SiGe layer has a Ge content of about 53%, a dislocation density lower than 10⁶ cm⁻² and a surface roughness smaller than 1 nm, and consequently is desirable for the fabrication of MOS devices in the CMOS fabricating process. The structure having the SiGe layer with high Ge content formed on the silicon substrate is shown in FIG. 5.

### EXAMPLE 3

Firstly, a Si substrate 310 is prepared, A SiO₂ dielectric layer 320 with a desired thickness (for example 1 um) is deposited or grown on the Si substrate 310 by the LPCVD process according to the size of the desired channel layer with high Ge content. The hole with a desired size (for example with a length of 500 nm) is formed on the SiO₂ dielectric layer 320 along <110> crystal orientation of the Si substrate 310 by lithographing and etching processes. The obtained hole has an aspect ratio of 2 to guarantee that the side wall, i.e. the SiO₂ dielectric layer 320, of the hole may filter most dislocation lines. Then Ge or SiGe with high Ge content is grown at 450° C. by a RPCVD equipment to form a channel layer 330 with high Ge content. According to this example, taking SiGe with high Ge content as an example, GeH₄ with a flow rate of about 450 sccm and SiH₄ with a flow rate of about 0.05 slm may be used as precursors and at the same time a HCl gas with a flow rate of about 0.10 slm is introduced to reduce the nucleating rate and the growth rate of SiGe on the SiO₂ dielectric layer 320. Therefore, the SiGe epitaxy occurs on the Si substrate 110 exposed in the hole to guarantee a two dimensional growth of the SiGe so that the SiGe layer with high Ge content formed on the Si substrate may be provided with a desired low dislocation density and low surface roughness. In this example, the obtained SiGe layer has a Ge content of about 92%, a dislocation density lower than 10⁶ cm⁻² and a surface roughness smaller than 1 nm, and consequently is desirable for the fabrication of MOS devices in the CMOS fabricating process. A structure having the SiGe layer with high Ge content formed on the Si substrate is shown in FIG. 6.

### EXAMPLE 4

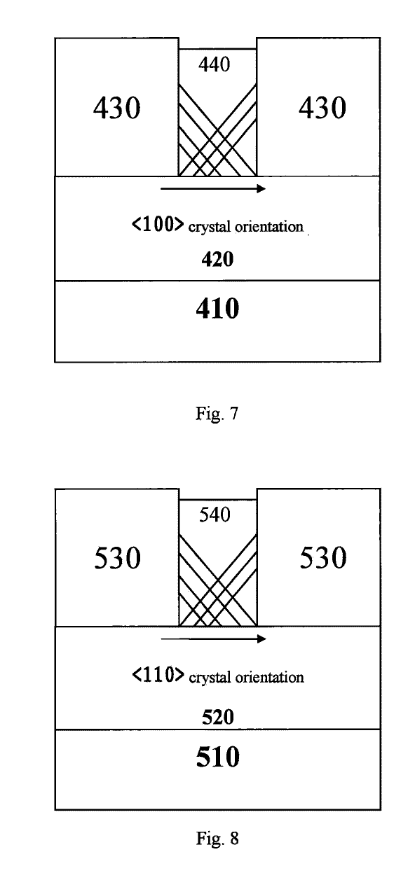

Firstly, a Si wafer 410 is prepared. A SiGe layer 420 with low Ge content, for example, a SiGe layer 420 with a Ge content less than 30%, is grown on the wafer 410 and may be used as a substrate. Then a SiO₂ dielectric layer 430 with a desired thickness, for example 1 um, may be formed on the SiGe layer 420 with low Ge content by the LPCVD process according to the size of the desired channel layer with high Ge content. The hole with a desired size, for example with a length of 500 nm, may be formed in the SiO₂ dielectric layer 430 along <100> crystal orientation of the SiGe layer 420 with a low Ge content by lithographing and etching. The obtained hole may have an aspect ratio of about 2 to guarantee that the side wall of the hole may filter most dislocation lines. Then Ge or SiGe with high Ge content may be grown at 500° C. by a RPCVD device to form a channel layer 440 with a high Ge content. According to this example, taking the SiGe with a high Ge content as an example, GeH₄ with a flow rate of about 400 sccm and SiH₄ with a flow rate of about 0.05 slm may be used as precursors and, at the same time, a HCl gas with a flow rate of about 0.10 slm may be introduced to reduce the nucleating rate and the growth rate of the SiGe on the SiO₂ dielectric layer 430. Therefore, the SiGe epitaxy occurs on the surface of the SiGe layer 420 exposed in the hole to guarantee a two dimensional growth of SiGe so that the SiGe layer with high Ge content with a desired low density of dislocations and low surface roughness may be obtained accordingly. In this example, the obtained SiGe layer may have a Ge content of about 87%, a dislocation density lower than 10⁶ cm⁻²and a surface roughness smaller than 1 nm, and consequently is desirable for the fabrication of MOS devices in the CMOS fabricating process. A structure of the SiGe layer with high Ge content in this example is shown in FIG. 7.

### EXAMPLE 5

Firstly, a Si wafer 510 is prepared. A SiGe layer 520 with low Ge content (for example, a SiGe layer 520 with Ge content less than 30%) is grown on the wafer 510 and is used as a substrate. Then a SiO₂ dielectric layer 530 with a desired thickness (for example 1 um) is formed on the SiGe layer 520 with low Ge content by the LPCVD process according to the size of the desired channel layer with high Ge content. The hole with a desired size, for example with a length of 500 nm, is formed in the SiO₂ dielectric layer 530 along <110> crystal orientation of the SiGe layer 520 with low Ge content by lithographing and etching processes. The obtained hole has an aspect ratio of 2 to guarantee that the side wall of the hole may filter most dislocation lines. Then Ge or SiGe with high Ge content is grown at 450° C. by a RPCVD equipment to form a channel layer 540 with high Ge content. According to this example, GeH₄ with a flow rate of about 450 sccm and SiH₄ with a flow rate of about 0.05 slm may be used as precursors and at the same time a HCl gas with a flow rate of about 0.10 slm is introduced to reduce the nucleating rate and the growth rate of the SiGe on the SiO₂ dielectric layer 530. Therefore, the SiGe epitaxy occurs on the surface of the SiGe layer 520 exposed in the hole to guarantee a two dimensional growth of the SiGe so that the SiGe layer with high Ge content has a desired low density of dislocations with low surface roughness. In this example, the obtained SiGe layer has a Ge content of about 92%, a dislocation density lower than 10⁶ cm⁻² and a surface roughness smaller than 1 nm, and consequently is desirable for the fabrication of MOS devices in the CMOS fabricating process. A structure of the SiGe layer with high Ge content in this example is shown in FIG. 8.

### EXAMPLE 6

This example is different from the above ones in that, after the hole is formed, the Ge or SiGe with high Ge content is grown at 350° C. by a RPCVD equipment to form a channel layer with high Ge content.

Although in the above examples or embodiments, a Ge layer or a SiGe layer with high Ge content, described as an example, is formed accordingly, in other embodiments of the present disclosure, a first relaxed SiGe layer with high Ge content may be grown by the RPCVD and then a second strained SiGe layer with higher Ge content or a second strained Ge layer may be grown by the RPCVD. Alternatively, a plurality of first relaxed SiGe layers with different Ge contents may be grown by the RPCVD and then a plurality of second strained SiGe layers or strained Ge layers may be grown on the plurality of relaxed SiGe layers by the RPCVD. These structures are all fallen within the scope to be protected by the claims of the present disclosure.

Although explanatory embodiments have been shown and described, it would be appreciated by those skilled in the art that changes, alternatives, and modifications all falling into the scope of the claims and their equivalents may be made in the embodiments without departing from spirit and principles of the disclosure.

What is claimed is:

1. A method for forming a channel layer with high Ge content on a substrate, comprising steps of:
preparing the substrate;
forming a dielectric layer on the substrate;
lithographing and etching the dielectric layer to form at least one hole in the dielectric layer to grow a channel layer with high Ge content; and
growing the channel layer with high Ge content in the at least one hole by a low temperature reduced pressure chemical vapor deposition.

2. The method according to claim 1, wherein the channel layer with high Ge content comprises a Ge layer or a SiGe layer with high Ge content.

3. The method according to claim 2, wherein the SiGe layer with high Ge content has a Ge content larger than 50%.

4. The method according to claim 1, wherein the step of forming the channel layer with high Ge content in the at least one hole by a low temperature reduced pressure chemical vapor deposition further comprises steps of:
forming a relaxed SiGe layer with high Ge content in the at least one hole by the low temperature reduced pressure chemical vapor deposition; and
forming a strained SiGe layer or a strained Ge layer with higher Ge content than that of the relaxed SiGe layer on the relaxed SiGe layer by the low temperature reduced pressure chemical vapor deposition.

5. The method according to claim 2, wherein the low temperature reduced pressure chemical vapor deposition is performed at about 350° C. to about 550° C.

6. The method according to claim 5, wherein SiH₄ and GeH₄ are used as precursors during the low temperature reduced pressure chemical vapor deposition.

7. The method according to claim 6, further comprising:
introducing a HCl gas during the low temperature reduced pressure chemical vapor deposition to reduce a nucleating rate and a growth rate of Ge or SiGe on the dielectric layer.

8. The method according to claim 2, wherein the substrate comprises a Si substrate or a SiGe layer with low Ge content forming on the Si substrate.

9. The method according to claim 1, wherein all of the at least one hole has a aspect ratio larger than 1.
